(19) United States
(12) Patent Application Publication
(10) Pub. No.: US 2024/0347344 A1
(43) Pub. Date: Oct. 17, 2024

(54) PLANARIZATION APPARATUS, PLANARIZATION METHOD, AND PRODUCT MANUFACTURING METHOD

(71) Applicant: CANON KABUSHIKI KAISHA, Tokyo (JP)

(72) Inventors: SHINICHIRO KOGA, Tochigi (JP); YUKIO NAKANO, Tochigi (JP)

(21) Appl. No.: 18/633,312

(22) Filed: Apr. 11, 2024

(30) Foreign Application Priority Data
Apr. 14, 2023 (JP) 2023-066472

(51) Int. Cl. H01L 21/3105; H01L 21/66; H01L 21/67

(52) U.S. Cl. CPC H01L 21/31051; H01L 21/67126; H01L 22/20

(57) ABSTRACT

Whether to perform planarization processing is determined by projecting a pressing member in a state where a planarization member held by a member holding unit is not in contact with a composition on a substrate held by a substrate holding unit. Determining whether to perform the planarization processing in such a manner enables the planarization member used to planarize the composition on the substrate to be stably separated.

### BACKGROUND

### Field of the Disclosure

The present disclosure relates to a planarization apparatus, a planarization method, and a product manufacturing method.

### Description of the Related Art

As the demand for the miniaturization of semiconductor devices increases, a micromachining technique for molding and curing an uncured curable composition on a substrate using a member (also referred to as a mold) to pattern the composition on the substrate is attracting attention in addition to conventional photolithography techniques. Such a technique is called an imprint technique, and can form a fine pattern on the order of several nanometers on a substrate.

A technique for planarizing a substrate using an imprint technique has been discussed in recent years (Japanese Unexamined Patent Application Publication [Translation of PCT Application] No. 2011-529626). The technique discussed in Japanese Unexamined Patent Application Publication (Translation of PCT Application) No. 2011-529626 is to mold a planarized surface on a substrate by dropping a curable composition based on differences in substrate level and curing the curable composition with a planarization member (also referred to as a super straight) having a flat surface in contact with the dropped curable composition. Such a planarization technique typically uses a member of the same size as the substrate, and it takes a large force to separate the planarization member and the substrate. In view of this, a technique for assisting the separation after curing by thrusting a push pin (also referred to as a pressing member) against the planarization member from a substrate stage via a cutout (notch or orientation flat) in the substrate during the separation has been discussed (Japanese Unexamined Patent Application Publication [Translation of PCT Application] No. 2022-544891).

### SUMMARY

According to an aspect of the present disclosure, a planarization apparatus for planarizing a composition on a substrate using a planarization member includes a substrate holding unit configured to hold the substrate, a member holding unit configured to hold the planarization member, a pressing member configured to be projected in a direction from the substrate to the planarization member, and a control unit configured to determine whether to perform planarization processing by projecting the pressing member with the planarization member not in contact with the composition, the planarization processing including bringing the substrate and the planarization member into contact via the composition.

Further features of various embodiments will become apparent from the following description of exemplary embodiments with reference to the attached drawings.

### BRIEF DESCRIPTION OF THE DRAWINGS

FIGS. 1A to 1C are schematic diagrams illustrating a configuration of a planarization apparatus.

FIGS. 2A to 2C are diagrams for describing planarization processing performed by the planarization apparatus.

FIG. 3 is a flowchart illustrating a procedure of the planarization processing.

FIG. 4 is a flowchart illustrating processing for checking the positions of a substrate and a planarization member in the planarization processing.

FIG. 5 is a diagram illustrating a positional relationship between the planarization member, the substrate, a cutout, and a pressing member.

FIGS. 6A to 6C are diagrams for describing a separation step.

FIGS. 7A and 7B are diagrams illustrating examples where the pressing member is unable to assist separation.

FIGS. 8A to 8D are diagrams illustrating the processing for checking the positions of the substrate and the planarization member in the planarization processing.

FIG. 9 is a flowchart illustrating processing for checking the positions of a substrate and a planarization member in planarization processing.

FIGS. 10A and 10B are diagrams illustrating how to check the operation of the pressing member.

### DESCRIPTION OF THE EMBODIMENTS

According to the planarization technique discussed in Japanese Unexamined Patent Application Publication (Translation of PCT Application) No. 2022-544891, the cutout in the substrate and the push pin are desirably located at the same position on the substrate holding unit. If their positions are different, the push pin can fail to reach the planarization member and assist separation. Similarly, if the planarization member does not overlap the position of the push pin, the push pin can be unable to assist separation. More specifically, if the substrate and the planarization member are laminated with either one deviated from the push pin, the substrate and the planarization member are inseparable and the laminate of the planarization member and the substrate and turns out to be a defective item. Moreover, the laminate of the planarization member and the substrate can be difficult to automatically carry out, in which case the operator is expected to stop the planarization apparatus and manually carry out the laminate with a drop in the productivity of the planarization apparatus.

Exemplary embodiments will be described below with reference to the attached drawings. In the drawings, similar members are denoted by the same reference numerals, and a redundant description thereof will be omitted.

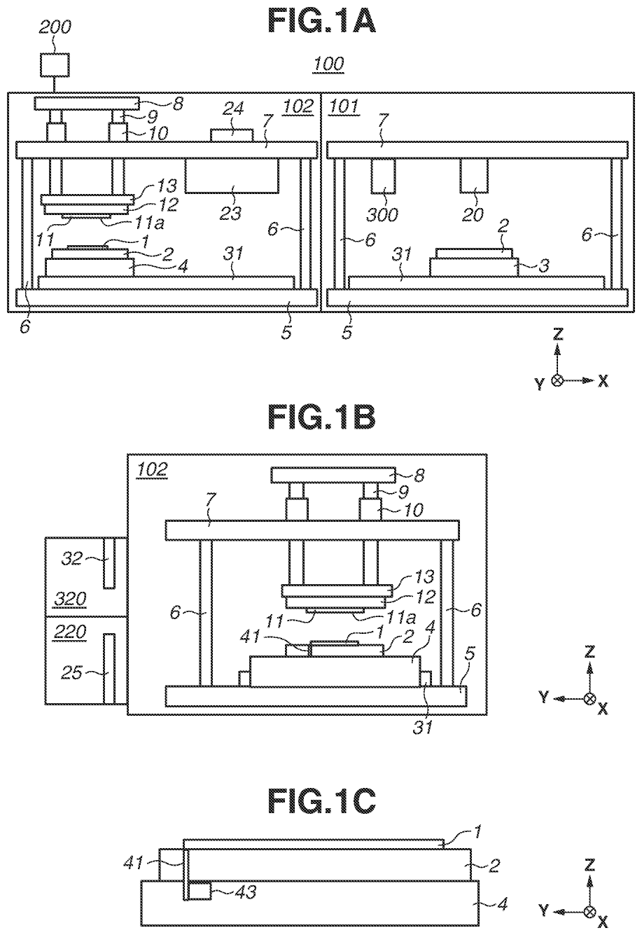

FIGS. 1A to 1C are schematic diagrams illustrating a configuration of a planarization apparatus 100 (molding apparatus). FIG. 1A is a view of the planarization apparatus 100 from a Y-axis side. FIG. 1B is a view of the planarization apparatus 100 from an X-axis side. FIG. 1C is a diagram illustrating a substrate holding unit 2 and a substrate stage 4 of a second processing unit 102 to be described below. The planarization apparatus 100 is configured to perform molding processing for molding a curable composition on a substrate 1. Specifically, the planarization apparatus 100 includes a first processing unit 101, the second processing unit 102, a substrate conveyance processing unit 220, and a member conveyance processing unit 320.

The first processing unit 101 performs an application step of applying the curable composition onto the substrate 1. The second processing unit 102 performs a contact step of bringing the curable composition on the substrate 1 and a planarization member 11 into contact, a curing step of curing the curable composition with the planarization member 11 in contact, and a separation step of separating the cured curable composition and the planarization member 11. In planarization layer molding processing, the foregoing steps are performed in order. While the present exemplary embodiment will be described in conjunction with an example using the first processing unit 101 and the second processing unit 102, the planarization apparatus 100 may include a single processing unit for performing the foregoing steps.

In this specification and the attached drawings, directions are expressed in an XYZ coordinate system with directions parallel to the surface of the substrate 1 as an XY plane. Directions parallel to the X-, Y-, and Z-axes of the XYZ coordinate system will be referred to as X, Y, and Z directions, respectively. Rotation about the X-axis, rotation about the Y-axis, and rotation about the Z-axis will be denoted by θX, θY, and θZ, respectively. Control or driving related to the X-, Y-, and Z-axes refers to control or driving related to the direction parallel to the X-axis, the direction parallel to the Y-axis, and the direction parallel to the Z-axis, respectively. Control or driving related to θX-, θY-, and θZ-axes refers to control or driving related to rotation about an axis parallel to the X-axis, rotation about an axis parallel to the Y-axis, and rotation about an axis parallel to the Z-axis, respectively. Position is information identifiable based on coordinates on the X-, Y-, and Z-axes. Orientation is information identifiable from values on the θX-, θY-, and θZ-axes. Alignment means position and/or orientation control. In the present exemplary embodiment, positioning can include control for correcting or changing the shape of at least one of the substrate 1 and the planarization member 11.

The curable composition is one that cures when given curing energy (may also be referred to as uncured resin). Examples of the curing energy include electromagnetic waves and heat. Examples of the electromagnetic waves include light having a wavelength selected from the range of 10 nm or more and 1 mm or less, like infrared rays, visible light, and ultraviolet rays.

The curable composition is a composition curable by light irradiation or by heat. A light-curable composition, which cures when exposed to light, contains at least a polymerizable compound and a photopolymerization initiator, and may contain a nonpolymerizable compound or a solvent as appropriate. The nonpolymerizable compound is at least one type of compound selected from a group including sensitizers, hydrogen doners, internal releasing agents, surfactants, antioxidants, and polymer components. The curable composition is applied to the substrate 1 in a film form by a spin coater or a slit coater. Alternatively, the curable compound may be applied to the substrate 1 in the form of droplets, or islands or films made of connected droplets, by a liquid spray head. The curable composition has a viscosity (viscosity at 25° C.) of 1 mPa·s or more and 100 mPa·s or less, for example.

The planarization apparatus 100 can use a planarization member (also referred to as a mold or super straight) 11 having a flat surface 11a to mold a planarization film (planarization layer) of the curable composition on the substrate 1. In such a case, the curable composition is cured with the flat surface 11a in contact with the curable composition. Such a planarization apparatus 100 desirably simultaneously molds a planarization film on a plurality of shot areas on a substrate formed by another imprint apparatus, with the planarization member having substantially the same size as that of the substrate.

A representative example of the base material of the substrate 1 is a silicon wafer. However, this is not restrictive. The substrate 1 can be freely selected from known semiconductor device substrates made of aluminum, titanium-tungsten alloys, aluminum-silicon alloys, aluminum-copper-silicon alloys, silicon oxides, and silicon nitrides. The substrate 1 may be a substrate on which an adhesion layer is formed through surface treatment, such as silane coupling treatment, silazane treatment, and organic thin film deposition, for the sake of improved adhesion to the curable composition. The substrate 1 typically has, but is not limited to, a circular shape of 300 mm in diameter.

If light is used as the curing energy, the planarization member 11 is made of a material that allows the curing light to pass therethrough. For example, the planarization member 11 is made of at least one of the following: glass, quartz, a light transmitting resin such as polymethyl methacrylate (PMMA) and a polycarbonate resin, a transparent metal deposition film, a polydimethylsiloxane and other flexible films, a photocuring film, and a metal film.

The planarization member 11 may have a circular shape of 300 mm in diameter, substantially the same as the size of the substrate 1. However, this is not restrictive, and the planarization member 11 may be somewhat larger than the substrate 1 or have a rectangular outline.

The thickness of the planarization member 11 can be 0.25 mm or more and less than 2 mm, for example. However, the thickness is not limited thereto, as long as the planarization member 11 has rigidity to follow the surface shape of the substrate 1 when placed on the substrate 1. Moreover, the planarization member 11 has a flat surface to contact the curable composition on the substrate 1 and follow the surface shape of the substrate 1. The flat surface has the same size as that of the substrate 1 or a size greater than that of the substrate 1.

Next, a structure of the first processing unit 101 and the second processing unit 102 will be described with reference to FIGS. 1A to 1C. The following description is provided by using an example where ultraviolet (UV) rays are used as the curing energy. Examples of the curable composition usable here include monomers, such as acrylates and methacrylates.

As illustrated in FIGS. 1A to 1C, the first processing unit 101 and the second processing unit 102 each include a substrate holding unit 2 (substrate chuck), a stage driving unit 31, a base plate 5, posts 6, and a top plate 7.

The first processing unit 101 further includes a substrate stage 3, a dispenser 20 (droplet supply unit), and a detection unit 300. The second processing unit 102 further includes a substrate stage 4, a guide bar plate 8, guide bars 9, head driving units 10, a planarization member holding unit 12, and a head 13. The second processing unit 102 also includes an exposure unit 23 (curing unit) and a light source 24. In the second processing unit 102, the substrate stage 4 is equipped with a push pin 41 (pressing member). The planarization apparatus 100 further includes the substrate conveyance processing unit 220, a substrate conveyance unit 25, the member conveyance processing unit 320, and a control unit 200.

Each substrate holding unit 2 includes a chuck, such as a vacuum chuck and an electrostatic chuck, and holds the substrate 1 with the chuck. The substrate stages 3 and 4 are supported by the base plates 5 and support the substrate holding units 2. The substrate stages 3 and 4 are driven in the X-and Y-axis directions to position the substrate 1 held by the substrate holding units 2 to predetermined positions. The stage driving units 31 include linear motors or air cylinders, for example, and drive the substrate stages 3 and 4 at least in the X-and Y-axis directions. The stage driving units 31 may have a function of driving the substrate stages 3 and 4 in two or more axial directions (for example, six axial directions). The stage driving units 31 include rotation mechanisms, and drive the substrate holding units 2 or the substrate stages 3 and 4 about the OZ axis.

The planarization member holding unit 12 includes a chuck, such as a vacuum chuck and an electrostatic chuck, and holds the planarization member 11 with the chuck. The head 13 holds the planarization member holding unit 12 (member holding unit). The head driving units 10 drive the head 13 and thereby drive the planarization member holding unit 12 and the planarization member 11. The head driving units 10 may be configured to drive the planarization member 11 on a plurality of axes.

The posts 6 for supporting the top plates 7 are disposed on the base plates 5. The guide bars 9 of the second processing unit 102 are located through the top plate 7. Each guide bar 9 is fixed to the guide bar plate 8 at one end and to the head 13 at the other end. The head driving units 10 drive the guide bars 9 and thereby drive the head 13 in the Z-axis direction. In such a manner, the planarization member 11 held by the planarization member holding unit 12 can be brought into contact with the curable composition on the substrate 1, and the planarization member 11 can be separated from the curable composition on the substrate 1. The head driving units 10 may include a mechanism for driving the head 13 on an axis other than the Z-axis. The head driving units 10 can include a mechanism for driving the head 13 on a plurality of axes (e.g., three axes such, as the θX-, θY-, and Z-axes, or six axes, such as the X-, Y-, Z-, θX-, θY-, and θZ-axes).

The substrate conveyance processing unit 220 includes the substrate conveyance unit 25 including a conveyance hand, and a not-illustrated substrate storage shelf where substrates carried in from outside the planarization apparatus 100 and substrates processed by the processing units can be temporarily stored. The substrate conveyance unit 25 is configured to be able to convey a substrate between the substrate storage shelf, the first processing unit 101, and the second processing unit 102.

The planarization member 11 can be carried in from outside the planarization apparatus 100 by a planarization member conveyance unit 32 including a conveyance hand. The planarization member 11 can be conveyed and positioned on the planarization member holding unit 12 via the member conveyance processing unit 320, and held by the planarization member holding unit 12. The member conveyance processing unit 320 can include a storage shelf where the planarization member 11 can be stored. A transportable planarization member storage unit may be provided instead of the storage shelf.

The dispenser 20 (supply unit) included in the first processing unit 101 disposes or supplies an uncured (liquid) curable composition onto the substrate 1. The dispenser 20 can include discharge ports (nozzles) for discharging the curable composition, for example. The dispenser 20 supplies the curable composition onto the substrate 1 in droplets of small volumes (e.g., 1 picoliter) using a method such as a piezoelectric jet method or a micro solenoid method, for example. The number of discharge ports in the dispenser 20 is not limited in particular, and may be one or more. For example, the dispenser 20 has 100 or more discharge ports. Such a plurality of discharge ports is arranged in one or more lines, for example.

As illustrated in FIG. 1C, the substrate stage 4 of the second processing unit 102 is equipped with the push pin (pressing member) 41 to be projected from the substrate holding unit 2 toward the substrate 1. The push pin 41 functions as an assistance in separating the planarization member 11 from the curable composition on the substrate 1. Specifically, in separating the planarization member 11, the push pin 41 is projected toward the planarization member 11 through the gap area of a cutout in the substrate 1, such as a notch and an orientation flat. Projecting the push pin 41 to press the planarization member 11 with the substrate 1 held by the substrate holding unit 2 produces force in the direction of drawing the planarization member 11 away from the substrate 1, so that the step of separating the planarization member 11 can be assisted. The second processing unit 102 further includes a push pin contact detection unit 43 that detects the state of contact of the push pin 41 with an object such as the substrate 1 and the planarization member 11.

The detection unit 300 of the first processing unit 101 can detect the position of the cutout, such as a notch and an orientation flat, in the substrate 1 held on the substrate holding unit 2. Specifically, the detection unit 300 can include an optical sensor that can detect the outer profile of the substrate 1, or a small camera that can directly observe the shape of the substrate 1.

The exposure unit 23 has a window for letting the curing energy (e.g., light such as UV rays) provided from the light source 24 through. The curable composition can be cured by light irradiation in a state (curing position) where the substrate stage 4 holding the substrate 1 in contact with the planarization member 11 via the curable composition is opposed to the exposure unit 23.

The control unit 200 includes a processing unit and a storage unit, such as a memory, and controls the entire planarization apparatus 100. For example, the control unit 200 is constituted by a field programmable gate array (FPGA) or other programmable logic device (PLD), an application specific integrated circuit (ASIC), a general-purpose or dedicated computer with a built-in program, or a combination of all or some of these. The control unit 200 functions as a processing unit that controls the components of the planarization apparatus 100 in a comprehensive manner and performs planarization processing.

The planarization processing is an example of the molding processing for molding the curable composition on the substrate 1, and forms a film of the cured curable composition with a planarized surface. More specifically, in the planarization processing, the curable composition is planarized by bringing the flat surface 11a of the planarization member 11 into contact with the curable composition on the substrate 1 so that the flat surface 11a follows the surface shape of the substrate 1. The planarization processing is typically performed by lot, in other words, on a plurality of substrates included in the same lot.

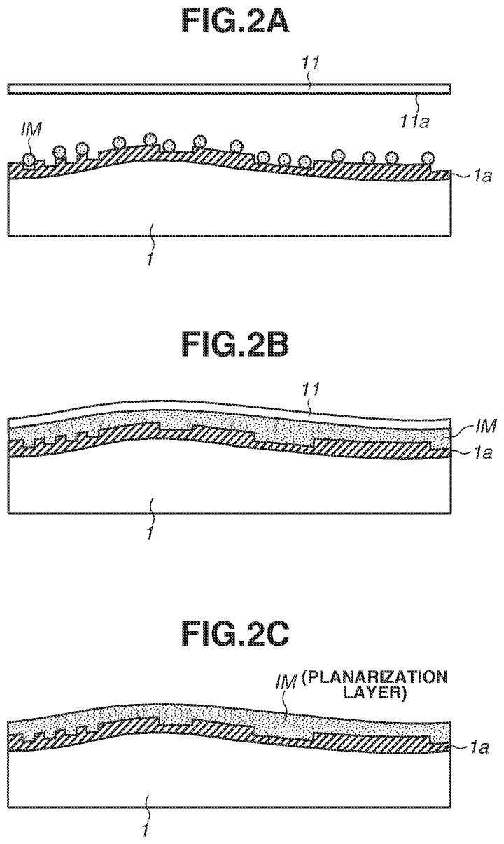

Next, an outline of the overall procedure of the planarization processing according to the present exemplary embodiment will be described with reference to FIGS. 2A to 2C. Here, processing for dropping the composition over the entire surface of the substrate 1 and bringing the composition and the planarization member 11 into contact to planarize the composition will be described. However, the composition on a partial area of the substrate 1 and the planarization member 11 may be brought into contact to planarize the composition.

Initially, as illustrated in FIG. 2A, the dispenser 20 of the first processing unit 101 supplies or disposes a curable composition IM onto a substrate 1 having an underlying pattern la. FIG. 2A illustrates a state where the curable composition IM is supplied onto the substrate 1 and the planarization member 11 (flat surface 11a) is yet to be brought into contact with the curable composition IM. The substrate 1 is then conveyed from the first processing unit 101 to the second processing unit 102 by the substrate conveyance unit 25.

Next, as illustrated in FIG. 2B, the head driving units 10 adjust the distance between the substrate 1 and the planarization member 11 so that the curable composition IM on the substrate 1 and the planarization member 11 (flat surface 11a) contact each other (contact step). FIG. 2B illustrates a state where the planarization member 11 is released from the planarization member holding unit 12, the flat surface 11a of the planarization member 11 is fully in contact with the curable composition IM on the substrate 1, and the flat surface 11a of the planarization member 11 follows the surface shape of the substrate 1.

In the state illustrated in FIG. 2B, the substrate stage 4 is then driven to the position of the exposure unit 23. The light source 24 irradiates the curable composition IM on the substrate 1 with the curing energy via the planarization member 11, so that the curable composition IM is cured (curing step).

Next, the substrate stage 4 is driven to the position of the head driving units 10. The head driving units 10 adjust the distance between the substrate 1 and the planarization member 11 so that the planarization member 11 is separated from the cured curable composition IM on the substrate 1. The planarization member 11 is held by the planarization member holding unit 12, in which state the substrate 1 and the planarization member 11 are separated in the Z-axis direction to separate the planarization member 11 from the curable composition IM on the substrate 1 (separation step). Here, the push pin 41 assists the separation.

The layer (planarization layer) of the curable composition IM having a uniform thickness can thus be molded over the entire substrate 1. FIG. 2C illustrates the state where the planarization layer of the cured curable composition IM is molded on the substrate 1. In other words, the planarization layer (planarization film) having a locally planarized surface can be molded of the cured curable composition IM by using the planarization member 11. Such a planarization method can mold the planarization layer over the entire substrate 1 in a single process, using the planarization member 11 having an area covering all the plurality of shot areas on the substrate 1.

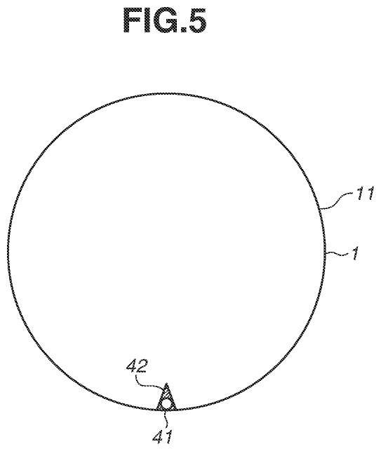

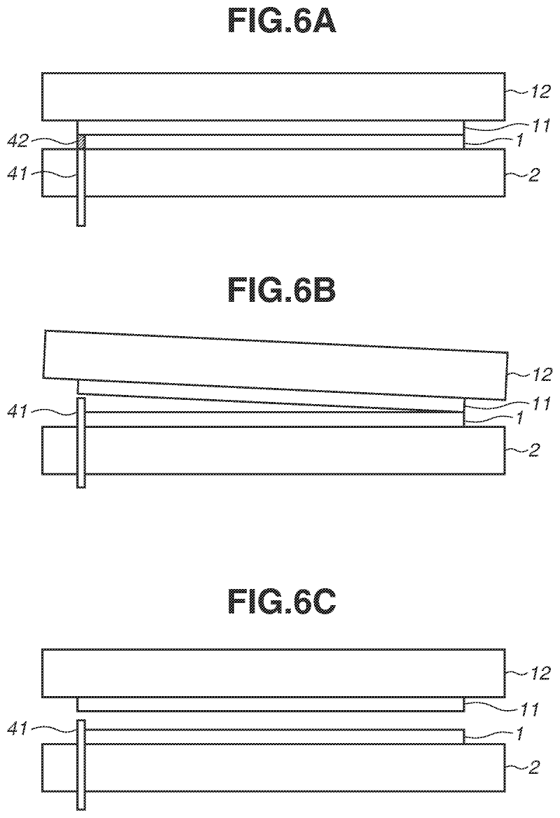

Next, the separation step of separating the planarization member 11 from the cured curable composition IM on the substrate 1 using the push pin 41 in the foregoing planarization processing will be described in detail with reference to FIGS. 5 and 6A to 6C.

As described above, separation may sometimes take a large amount of force since the curable composition IM is cured with the planarization member 11 in contact with the entire surface of the substrate 1. The technique for assisting the separation by providing the substrate stage 4 with the push pin 41 for applying force to the planarization member 11 through the cutout in the substrate 1 in the state where the substrate 1 and the planarization member 11 are laminated after the curing is thus effective. FIG. 5 is a diagram illustrating the positional relationship between the substrate 1 and the push pin 41. In this example, a cutout 42 in the substrate 1 is a notch. If properly aligned, the cutout 42 in the substrate 1 comes to the position of the push pin 41. At the timing of the separation processing where the planarization member 11 and the substrate 1 are laminated, the planarization member 11 overlaps the position of the push pin 41.

FIGS. 6A to 6C are diagrams for describing the procedure of the separation processing using the push pin 41. FIG. 6A is a diagram illustrating a state prior to the start of separation, where the flat surface 11a of the planarization member 11 is in contact with and follows the surface shape of the substrate 1 and the curable composition IM on the substrate 1 is cured. FIG. 6B is a diagram illustrating an operation during separation. The head driving units 10 lift up the planarization member 11 to separate the planarization member 11 from the cured curable composition IM on the substrate 1. Here, the push pin 41 in the substrate stage 4 is projected through the cutout 42 in the substrate 1 and thrusted against the planarization member 11 to assist separation. FIG. 6C illustrates the separated state. In this state, the planarization member 11 is fully separated from the cured curable composition IM on the substrate 1.

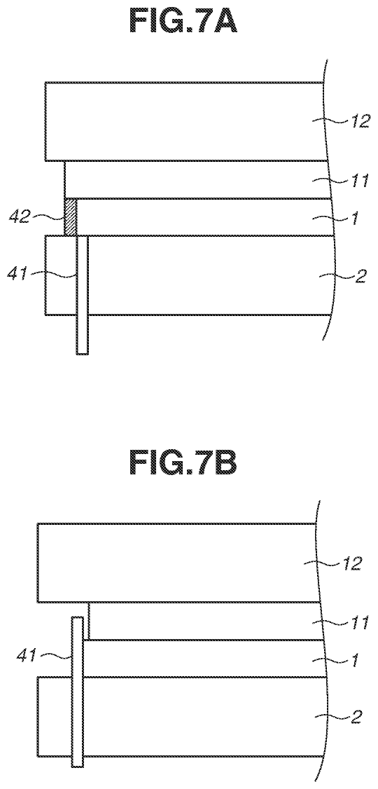

If the substrate 1 and the planarization member 11 have substantially the same size, the push pin 41 is desirably located at the same position as that of the cutout 42 in the substrate 1 held on the substrate holding unit 2 for the sake of pushing up the planarization member 11 from the substrate 1. By contrast, if the planarization member 11 is shaped to be somewhat larger than the substrate 1, the cutout 42 in the substrate 1 and the push pin 41 do not necessarily need to be located at the same position. Note that, however, the push pin 41 is still desirably located at a predetermined position where the push pin 41 does not interfere with the substrate 1 and can push up the planarization member 11 in lifting the planarization member 11 from the substrate 1. FIGS. 7A and 7B are diagrams illustrating examples where the push pin 41 is unable to assist separation. In FIGS. 7A and 7B, the curable composition IM on the substrate 1 is omitted.

According to the method for assisting separation using the push pin 41, if the substrate 1 is placed on the substrate holding unit 2 with the cutout 42 in the substrate 1 and the push pin 41 misaligned, the push pin 41 can interfere with the substrate 1 and be unable to assist separation as illustrated in FIG. 7A. The separation assistance also fails if the planarization member 11 does not overlap the position where the push pin 41 pushes the planarization member 11 (the planarization member 11 is misaligned with respect to the substrate 1) as illustrated in FIG. 7B. The planarization member 11 is sometimes unable to be held at such a desired position because of misalignment, in which state the separation assistance by the push pin 41 can be unavailable. If the separation assistance by the push pin 41 is thus unavailable and the planarization member 11 and the substrate 1 are inseparable, the laminate of the substrate 1 and planarization member 11 turns out to be a defective item. The laminate of the planarization member 11 and substrate 1 can even be difficult to automatically carry out of the planarization apparatus 100. In such a case, the operator is expected to stop the planarization apparatus 100 and manually remove the laminate, with a drop in the productivity of the planarization apparatus 100 since the planarization apparatus 100 is not normally usable. Moreover, the ejected laminate of the substrate 1 and the planarization member 11 is desirably processed for recycling.

In the present exemplary embodiment, as will be described in detail below, the push pin 41 is therefore driven to check whether the holding position of the substrate 1 and the holding position of the planarization member 11 are correct in advance before the substrate 1 and the planarization member 11 are laminated. In other words, by checking whether the substrate 1 and/or the planarization member 11 and the push pin 41 are in a positional relationship in which separation assistance is feasible in advance, the planarization member 11 can be stably separated from the curable composition IM on the substrate 1 using the push pin 41.

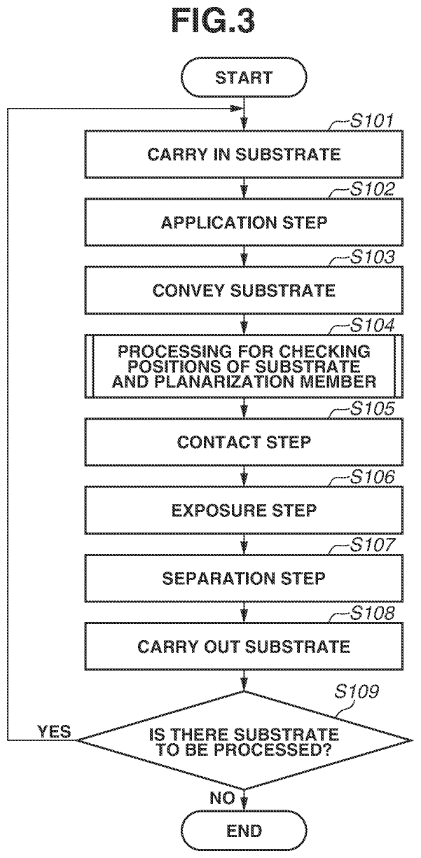

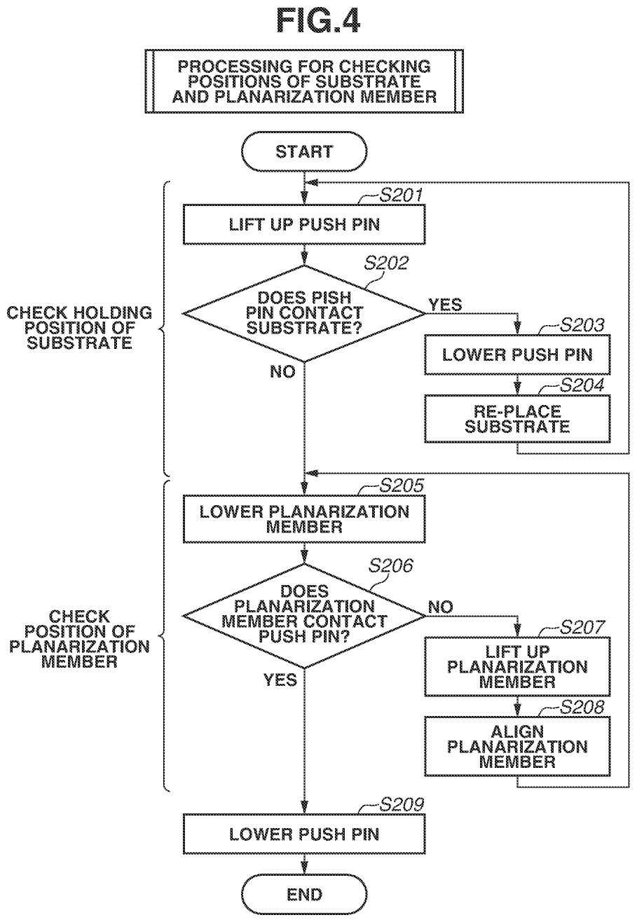

A first exemplary embodiment of the present disclosure will be described below. The procedure of the planarization processing according to the present exemplary embodiment will be described with reference to the flowcharts of FIGS. 3 and 4. The processing illustrated in the flowcharts of FIGS. 3 and 4 is implemented by the control unit 200 controlling the components of the planarization apparatus 100 in a comprehensive manner. The following description starts at a state where the planarization member 11 is held by the planarization member holding unit 12 of the second processing unit 102.

In step S101 of FIG. 3, the control unit 200 carries the substrate 1 into the planarization apparatus 100 and places the substrate 1 on the substrate holding unit 2 of the first processing unit 100 using the substrate conveyance unit 25. The control unit 200 measures the rotation of the substrate 1 about the Z-axis using the detection unit 300, and adjusts the rotation of the substrate 1 about the Z-axis based on the measurement.

In step S102, the control unit 200 applies the curable composition IM to the substrate 1 by dropping droplets of the curable composition IM on the substrate 1 placed on the substrate holding units 2 using the dispenser 20 (application step). Here, the control apparatus 200 may supply the curable composition IM while adjusting the amount of application based on level difference information due to a pattern already formed on the substrate 1.

In step S103, the control unit 200 conveys the substrate 1 from the first processing unit 101 to the second processing unit 102, places the substrate 1 on the substrate holding unit 2 of the second processing unit 102, and causes the substrate holding unit 2 to hold the substrate 1. In step S104, the control unit 200 checks the holding position of the substrate 1 on the substrate holding unit 2 and the position of the planarization member 11 with respect to the substrate 1. Details of the processing will be described below with reference to FIG. 4.

In step S105, the control unit 200 performs contact processing (contact step) for bringing the planarization member 11 held by the planarization member holding unit 12 into contact with the curable composition IM on the substrate 1. Specifically, the control unit 200 lowers the head 13 to lower the planarization member 11 attracted to and held by the planarization member holding unit 12, so that the contact between the curable composition IM on the substrate 1 and the planarization member 11 is started. Here, the control unit 200 gradually releases the attraction of the planarization member 11 by the planarization member holding unit 12 so that no air bubble remains between the planarization member 11 and the substrate 1. The control unit 200 places the planarization member 11 on the curable composition IM by eventually completely releasing the planarization member 11 from the planarization member holding unit 12. The curable composition IM on the substrate 1 and the planarization member 11 are in contact all over, with the flat surface 11a of the planarization member 11 following the surface shape of the substrate 1.

In step S106, the control unit 200 drives the substrate stage 4 to move the substrate 1 to under the exposure unit 23. Next, the control unit 200 irradiates the curable composition IM with the curing light (UV rays) from the light source 24 through the planarization member 11 to cure the curable composition IM (exposure step). While in the present exemplary embodiment the light source 24 functions as the curing unit, a unit other than a light source may be used as the curing unit.

In step S107, the control unit 200 drives the substrate stage 4 to move the substrate 1 to under the planarization member holding unit 12 again, and causes the planarization member holding unit 12 to attract and hold the planarization member 11 again while controlling the position of the planarization member holding unit 12 in the Z direction. The control unit 200 then separates the planarization member 11 from the cured curable composition IM on the substrate 1 (separation step). Here, if the head 13 is simply lifted up in the vertical direction (Z-axis direction), it requires a force as large as several hundreds of newtons (N) to separate the planarization member 11 from the curable composition IM. The application of such a large force to the planarization member 11 or the substrate 1 can break the pattern of the substrate 1, peel off the curable composition IM, or damage the planarization member 11. For such a reason, the separation step is performed using the push pin 41 as described above.

In step S108, with the planarization processing for a single substrate 1 performed by the planarization apparatus 100 completed, the control unit 200 carries the substrate 1 held by the substrate holding unit 2 out of the planarization apparatus 100 and returns the substrate 1 to a substrate conveyance container using the substrate conveyance unit 25.

In step S109, the control unit 200 determines whether there still is a substrate 1 to be processed. If there still is a substrate 1 to be processed (YES in step S109), the processing returns to step S101.

The planarization processing described with reference to the foregoing flowchart is just an example. While the planarization processing is described by using an example where the curable composition IM is applied inside the planarization apparatus 100, the planarization processing may be performed by using a substrate 1 to which the curable composition IM is applied outside the planarization apparatus 100.

Next, the processing for checking the positions of the substrate 1 and the planarization member 11 in step S104 will be described with reference to the flowchart of FIG. 4. The operations illustrated in steps S201 to S204 are performed to check the position of the substrate 1 and the push pin 41 and thereby check the holding position of the substrate 1 by the substrate holding unit 2. The planarization processing can be performed with the proper substrate position by performing at least the operations in steps S201 to S204 before the operations in steps S105 and the following steps.

The operations illustrated in steps S205 to S208 are performed to check the position of the planarization member 11 and the push pin 41 and thereby check the position of the planarization member 11 with respect to the substrate 1. In other words, by performing the processing for checking the holding position of the substrate 1 and the processing for checking the position of the planarization member 11, the control unit 200 can prevent the operations in steps S105 and the subsequent steps from being performed in a state incapable of separation assistance.

In step S201, the control unit 200 starts to lift the push pin 41 provided on the substrate stage 4 up in the Z-axis direction. The target lifting position of the push pin 41 is above the position in the Z-axis direction at which the planarization member 11 starts to make contact with the curable composition IM on the substrate 1 in step S105 of FIG. 3.

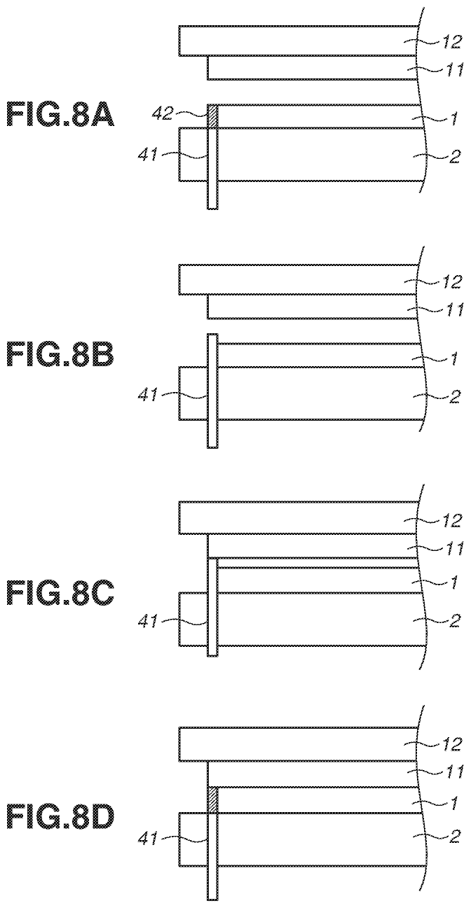

FIGS. 8A to 8D are lateral views of the push pin 41, the substrate 1, and the planarization member 11 during such processing. Again, the curable composition IM is omitted in FIGS. 8A to 8D. FIG. 8A illustrates a state after the substrate 1 is placed on the substrate stage 4 and before the push pin 41 is lifted up.

In step S202, the control unit 200 determines whether the end of the pish pin 41 contacts the bottom of the substrate 1 before the push pin 41 reaches the target position. Specifically, the control unit 200 projects the push pin 41 with the planarization member 11 not in contact with the curable composition IM on the substrate 1, and checks whether the end of the push pin 41 contacts the bottom of the substrate 1. If the end of the push pin 41 is determined to contact the bottom of the substrate 1, the control unit 200 immediately stops lifting up the push pin 41 since the substrate 1 can be misaligned as illustrated in FIG. 7A. Specifically, the contact with the substrate 1 can be detected by the push pin contact detection unit 43.

In step S202, if the push pin 41 is determined to contact the substrate 1 (YES in step S202), the control unit 200 stops lifting up the push pin 41 since the holding position of the substrate 1 held on the substrate stage 4 is incorrect, and the processing proceeds to step S203. In step S203, the control unit 200 lowers the push pin 41 to retract the push pin 41 into the substrate stage 4. In step S204, the control unit 200 re-places the substrate 1 on the substrate stage 4 using the substrate conveyance unit 25 to correct the misalignment of the substrate 1. The processing then returns to step S201, and the push pin 41 is lifted up again. The operations in steps S201 to S204 are repeated in order until the push pin 41 reaches the target position without contacting the substrate 1. The substrate 1 held at the proper position by the substrate holding unit 2 is thus subjected to the operations in steps S105 and the subsequent steps.

If, in step S202, the end of the push pin 41 is determined to contact the bottom of the substrate 1 before the push pin 41 reaches the target position, the control unit 200 may display information indicating the occurrence of the misalignment on a display unit (not illustrated) to notify the operator. An external notification unit (not illustrated) may notify an external device to be connected to the external notification unit of such information. Both notifications may be issued. Not only the occurrence of the misalignment but the absence of misalignment may be notified as a determination result of the processing performed in step S202. If the substrate 1 is not properly placed even through a predetermined number of times of repetitions of the operations in steps S201 to S204, the control unit 200 may abort the processing due to an error.

In step S202, if the push pin 41 is determined to be lifted up to the target position without contacting the substrate 1 as illustrated in FIG. 8B (NO in step S202), the processing proceeds to step S205. In step S205, with the push pin 41 stopped at the target position, the control unit 200 lowers the head 13 in the Z-axis direction to lower the planarization member 11 attracted to and held by the planarization member holding unit 12 toward the substrate 1. To determine whether the push pin 41 is lifted up to the specific target position, a sensor, such as an encoder for detecting the position of the push pin 41 in the Z direction, is disposed to locate the predetermined position of the push pin 41 using the sensor.

In step S206, the control unit 200 determines whether the planarization member 11 contacts the push pin 41 before the Z-axis position of the surface of the planarization member 11 successfully reaches the Z-axis position of the end of the push pin 41 in the process of lowering the head 13. The planarization member 11 does not contact the curable composition IM on the substrate 1 even if the head 13 is lowered to the Z-axis position of the end of the push pin 41.

Suppose that the planarization member 11 is detected to contact the push pin 41 before the head 13 reaches the predetermined position in the Z-axis direction where the end of the push pin 41 successfully makes contact with the surface of the planarization member 11. In such a case (YES in step S206), the processing proceeds to step S209 since the separation processing can be properly performed if the planarization processing is started, in other words, the planarization member 11 is located at the proper position. On the other hand, if the head 13 reaches the predetermined position without the planarization member 11 contacting the push pin 41 (NO in step S206), the control unit 200 stops lowering the head 13 and the processing proceeds to step S207. In such a case, the push pin 41 and the planarization member 11 may be misaligned as illustrated in FIG. 7B. In step S207, with the lowering of the head 13 stopped, the control unit 200 lifts the head 13 up to the position prior to the start of the lowering. In step S208, the control unit 200 aligns the planarization member 11 with respect to the substrate 1 on the X-and Y-axes.

Specifically, the control unit 200 drives the head driving units 10 to adjust the X-and Y-axes of the head 13 to align the planarization member 11 with respect to the position of the substrate 1.

The processing then returns to step S205 to lower the planarization member 11 again. The operations in steps S205 to S208 are repeated in order until the planarization member 11 contacts the push pin 41.

If, in step S206, the control unit 200 determines that the planarization member 11 does not contact the push pin 41, the control unit 200 may display the information on the display unit (not illustrated) to notify the operator. The external notification unit (not illustrated) may notify the external device of the information. Both notifications may be issued.

In step S209, the control unit 200 temporarily stops lowering the head 13, and lowers the push pin 41 to the position prior to the start of the lift-up so that the push pin 41 is retracted into the substrate stage 4 as illustrated in FIG. 8D. The processing then proceeds to step S105 to start the planarization processing.

As described above, whether the substrate 1 and the planarization member 11 are in a positional relationship in which separation assistance is feasible is checked in advance by driving the push pin 41 before the substrate 1 and the planarization member 11 are brought into contact for planarization processing. In other words, at least whether the substrate 1 is in a positional relationship in which separation assistance is feasible is checked in advance by driving the push pin 41 with the planarization member 11 not in contact with the curable composition IM, and whether to perform the planarization processing is determined based on the detection result of the prior check. This enables the push pin 41 to stably separate the planarization member 11 from the curable composition IM on the substrate 1.

Up to this point, one exemplary embodiment of the present disclosure has been described. However, some embodiments are not limited to the exemplary embodiment, and various modifications and changes can be made without departing from the gist thereof. For example, in the present exemplary embodiment, the positions of the substrate 1 and the planarization member 11 are described to be checked by using sensors, such as the push pin contact detection unit 43 and the encoder for detecting the position of the push pin 41 in the Z direction. Alternatively, the force for driving the push pin 41 may be detected from the current value of the motor driving the push pin 41, and the state of contact of the push pin 41 may be detected from the driving force and the amount of change in the position of the push pin 41. Moreveor, the contact of the push pin 41 with the planarization member 11 may be detected based on the state of the head 13 (head position and head driving force) as well as the accessory unit of the pish pin 41. The positions of the substrate 1 and the planarization member 11 may be checked by combining these units and techniques as appropriate. While in the present exemplary embodiment the position of the planarization member 11 is checked by lowering the planarization member 11, the position may be detected by further lifting up the push pin 41. Specifically, the distance between the end of the push pin 41 and the planarization member 11 may be reduced by lifting up the push pin 41 or lowering the planarization member 11, as long as the contact between the planarization member 11 and the push pin 41 is detectable using the push pin contact detection unit 43.

A second exemplary embodiment of the present disclosure will be described below. In the first exemplary embodiment, the position of the planarization member 11 is described to be always checked after the holding position of the substrate 1 on the substrate holding unit 2 is checked. The holding position of the substrate 1 on the substrate holding unit 2 varies each time the substrate 1 is carried into the substrate holding unit 2. The operations in steps S201 to S204 are to be performed each time a substrate 1 is carried in. By contrast, the same planarization member 11 is typically used for a plurality of substrates 1. Since the position of the planarization member 11 with respect to the planarization member holding unit 12 usually changes only when the planarization member 11 is replaced, the operations in steps S205 to S208 are not necessary to perform each time. However, the position of the planarization member 11 on the planarization member holding unit 12 can sometimes deviate since the operation of separating the planarization member 11 from the substrate 1 exerts a large force on the planarization member 11.

In the present exemplary embodiment, whether to check the position of a planarization member 11 is determined in using the same planarization member 11 for the next processing. If the position of the planarization member 11 is determined to be checked, processing for checking the position of the planarization member 11 with respect to a substrate 1 is performed by checking the position of the planarization member 11 and a push pin 41.

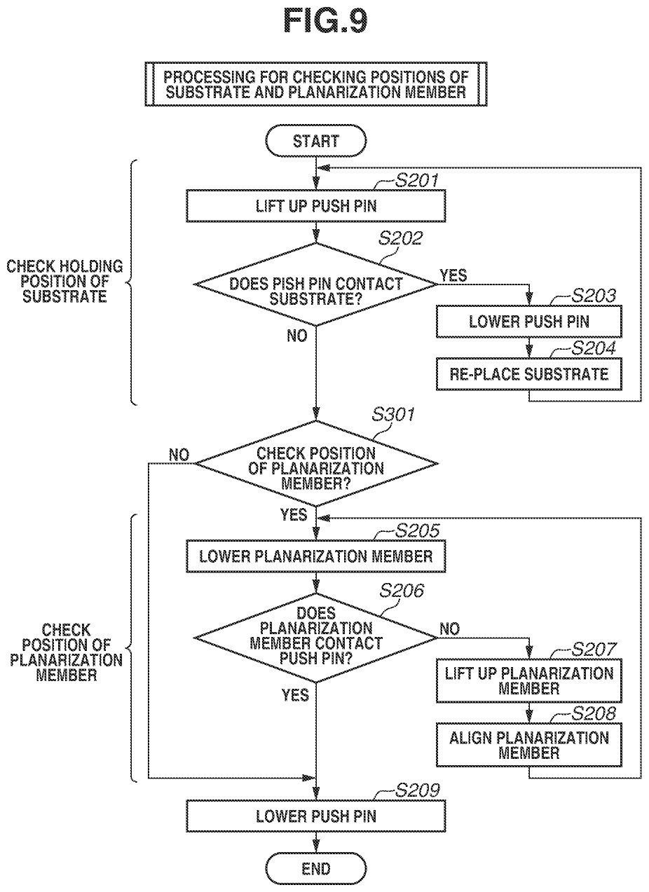

The procedure of planarization processing according to the present exemplary embodiment will be described with reference to the flowchart of FIG. 9. The processing illustrated in the flowchart of FIG. 9 is implemented by a control unit 200 controlling the components of a planarization apparatus 100 in a comprehensive manner. The processing of steps S201 to S209 in FIG. 9 is similar to that of FIG. 4, and a description thereof will thus be omitted.

In the operations in steps S201 to S204 in FIG. 9, the control unit 200 checks the position of the substrate 1 and the push pin 41 and thereby checks the holding position of the substrate 1 held by a substrate holding unit 2. In step S301, the control unit 200 then determines whether to check the position of the planarization member 11 with respect to the substrate 1. Specifically, the control unit 200 determines to check the position of the planarization member 11 in processing the substrate 1 immediately after the planarization member 11 is attracted to and held by a planarization member holding unit 12, or after the planarization processing is performed on a predetermined number of substrates 1.

The control unit 200 may also determine to check the position of the planarization member 11 in step S301 if the force (separation force) acting on the planarization member 11 in any of the X, Y, and Z directions is greater than or equal to a predetermined magnitude during the separation processing of the planarization member 11 and the substrate 1 in the immediately previous planarization processing. An example of the unit for measuring the magnitude of the separation force may be a force sensor (separation force acquisition unit, not illustrated) included in the planarization member holding unit 12. Specifically, if the separation force in separating the planarization member 11 from the substrate 1 in the process of the immediately previous planarization processing is greater than a predetermined value, the position of the planarization member 11 is determined to be checked before the next planarization processing.

In step S301, if the position is determined to be checked (YES in step S301), the processing proceeds to step S205. In steps S205 to S209, the control unit 200 checks the position of the planarization member 11. If, in step S301, the control unit 200 determines that the position is not to be checked (NO in step S301), the processing proceeds to step S209. In step S209, the control unit 200 lowers the push pin 41 to the position prior to the start of the lift-up of the push pin 41 so that the push pin 41 is retracted into a substrate stage 4. The processing then proceeds to step S105 to start the planarization processing.

As described above, in the present exemplary embodiment, the operations in steps S205 to S209 are performed only if the position of the planarization member 11 is determined to be checked. This can prevent unnecessary position checks on the planarization member 11 and improve the productivity of the planarization apparatus 100.

In the processing for checking the holding position of the substrate 1, the substrate 1 may be conveyed to a first processing unit 101 and positioned again using a detection unit 300 instead of the technique for re-placing the substrate 1 on the substrate stage 4 using the substrate conveyance unit 25 as described in step S204. Also, the substrate 1 may be carried out of a second processing unit 102 or the planarization apparatus 100 for position adjustment.

The curable composition IM on the substrate 1 may fail to produce a desired curing result in the subsequent curing processing due to a change over time (e.g., volatilization), turning out to be a defective item. If the substrate 1 is carried out of the second processing unit 102 or the planarization apparatus 100, the applied curable composition IM is therefore desirably removed (reworked) to repeat the processing from the application step S102.

Even if the holding position of the substrate 1 is determined to be correct in step S202, the control unit 200 may determine whether to carry the substrate 1 out depending on the elapsed time since the application processing of the curable composition IM to the substrate 1.

In the processing of checking the position of the planarization member 11, the planarization member 11 may be carried out of the second processing unit 102 or the planarization apparatus 100 for adjustment instead of the technique for adjusting the X-and Y-axes of the head 13 as described in step S208. Specifically, the planarization member 11 may be held by a planarization member conveyance unit 32 and then placed on the planarization member holding unit 12 again to adjust the holding position of the planarization member 11 on the planarization member holding unit 12. The relative position of the planarization member holding unit 12 and the planarization member 11 can be thereby corrected, which enables alignment with respect to the substrate 1.

In checking the holding position of the substrate 1 and the position of the planarization member 11 in FIGS. 4 and 9, there may be a step of checking whether the push pin 41 is properly driven (push pin driving check) in the case where the substrate 1 or the planarization member 11 is determined to be misaligned.

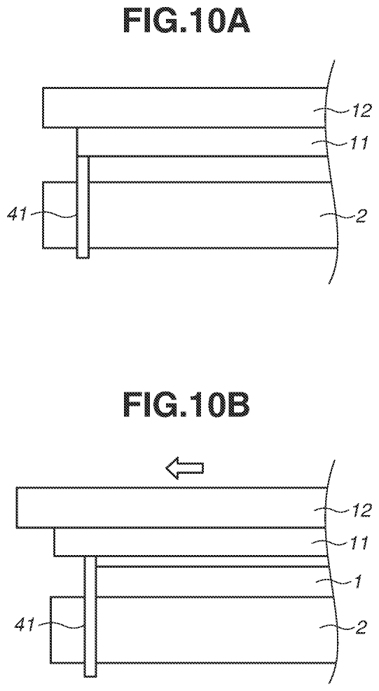

FIGS. 10A and 10B are diagrams illustrating the push pin driving check step. FIG. 10A illustrates an example of the check processing to be performed after the substrate 1 is determined to be misaligned in checking the holding position of the substrate 1. The operation of the push pin 41 is checked when the substrate 1 is carried out for position adjustment. Specifically, after the push pin 41 is lifted up as in step S201, the planarization member 11 is lowered as in step S206 to check for contact between the push pin 41 and the planarization member 11 as in step S206. If the contact between the push pin 41 and the planarization member 11 is detected by a push pin contact detection unit 43, the push pin 41 can be determined to be operating properly.

FIG. 10B illustrates an example of the check processing to be performed after the planarization member 11 is determined to be misaligned in checking the position of the planarization member 11. The planarization member 11 is moved in parallel with the surface of the substrate 1 so that the planarization member 11 always overlaps the position of the push pin 41, and then whether the push pin 41 and the planarization member 11 contact each other is checked as in step S206. The proper operation of the push pin 41 can thereby be determined. Specifically, after the planarization member 11 is moved in parallel with the surface of the substrate 1, the push pin 41 is lifted up as in step S201 (the push pin 41 lifts up if operating properly). The planarization member 11 is then lowered as in step S205, and the push pin 41 and the planarization member 11 are checked for contact as in step S203. If the push pin 41 and the planarization member 11 are determined to contact each other, the push pin 41 can be determined to be operating properly.

According to the exemplary embodiment described above, the push pin 41 can be driven in advance to check whether the holding position of the substrate 1 and the position of the planarization member 11 are correct before the substrate 1 and the planarization member 11 are laminated. In other words, by checking whether the substrate 1 and the planarization member 11 are in a positional relationship in which separation assistance is feasible, in advance before the planarization processing, the planarization member 11 can be stably separated from the curable composition IM on the substrate 1. This is expected to prevent a drop in the productivity of the planarization apparatus 100.

### (Product Manufacturing Method)

Next, a method for manufacturing products (such as semiconductor integrated circuit [IC] elements, liquid crystal display elements, color filters, and micro-electromechanical systems [MEMS]) using the foregoing planarization apparatus or planarization method will be described. This manufacturing method includes the steps of bringing a composition disposed on a substrate (such as a wafer and a glass substrate) and a planarization member into contact for planarization, curing the composition, and separating the composition and the planarization member.

Products are manufactured by patterning the substrate having the planarized composition using a lithographic apparatus, and applying other known processing steps to the patterned substrate. Examples of the other known processing steps include etching, resist stripping, dicing, bonding, and packaging. According to this manufacturing method, products of higher quality than heretofore can be manufactured.

While exemplary embodiments have been described above, it will be understood that some embodiments are not limited to these exemplary embodiments, and various modifications and changes can be made without departing from the gist thereof.

While the present disclosure has described exemplary embodiments, it is to be understood that some embodiments are not limited to the disclosed exemplary embodiments. The scope of the following claims is to be accorded the broadest interpretation so as to encompass all such modifications and equivalent structures and functions.

This application claims priority to Japanese Patent Application No. 2023-066472, which was filed on Apr. 14, 2023 and which is hereby incorporated by reference herein in its entirety.

What is claimed is:

1. A planarization apparatus for planarizing a composition on a substrate using a planarization member, the planarization apparatus comprising:
a substrate holding unit configured to hold the substrate;
a member holding unit configured to hold the planarization member;
a pressing member configured to be projected in a direction from the substrate to the planarization member; and
a control unit configured to determine whether to perform planarization processing by projecting the pressing member with the planarization member not in contact with the composition, the planarization processing including bringing the substrate and the planarization member into contact via the composition.

2. The planarization apparatus according to claim 1, wherein the control unit is configured to make a determination as to whether a holding position of the substrate held by the substrate holding unit is correct by projecting the pressing member with the planarization member not in contact with the composition, and determine whether to perform the planarization processing based on the determination.

3. The planarization apparatus according to claim 2, further comprising a contact detection unit configured to detect contact between the pressing member and an object,
wherein the control unit is configured to, in a case where the pressing member is projected with the planarization member not in contact with the composition and the contact detection unit detects contact with the substrate, determine that the holding position of the substrate held by the substrate holding unit is incorrect.

4. The planarization apparatus according to claim 2, wherein the control unit is configured to, in a case where the holding position of the substrate is determined to be incorrect, control adjustment of the holding position of the substrate held by the substrate holding unit.

5. The planarization apparatus according to claim 2, wherein the control unit is configured to, in a case where the holding position of the substrate is determined to be correct, determine whether a position of the planarization member held by the member holding unit is correct by projecting the pressing member with the planarization member not in contact with the composition.

6. The planarization apparatus according to claim 5, further comprising a force sensor configured to acquire a separation force in separating the planarization member from the substrate in the planarization processing,
wherein the control unit is configured to, in a case where the separation force acquired by the force sensor in immediately previous planarization processing is greater than a predetermined value, control determination as to whether the position of the planarization member held by the member holding unit is correct.

7. The planarization apparatus according to claim 5, further comprising a contact detection unit configured to detect contact between the pressing member and an object,
wherein the control unit is configured to, in a case where the contact detection unit detects contact in reducing a distance between the pressing member and the planarization member, determine that the position of the planarization member held by the member holding unit is correct.

8. The planarization apparatus according to claim 1, wherein the pressing member is used to assist separation of the substrate and the planarization member contacting via the composition.

9. The planarization apparatus according to claim 1, wherein the control unit is configured to notify at least one of a display unit and an external device connected to the planarization apparatus of a determination as to whether to perform the planarization processing.

10. A planarization apparatus for planarizing a composition on a substrate using a planarization member, the planarization apparatus comprising:
a substrate holding unit configured to hold the substrate;
a member holding unit configured to hold the planarization member;
a pressing member configured to be projected in a direction from the substrate to the planarization member;
a contact detection unit configured to detect contact between the pressing member and an object; and
a control unit configured to project the pressing member with the planarization member not in contact with the composition, and control at least one of the pressing member, the substrate holding unit, and the member holding unit based on a result of detection made by the contact detection unit.

11. A planarization method for planarizing a composition on a substrate using a planarization member, the planarization method comprising:
projecting, as a first projection, a pressing member in a direction from the substrate held by a substrate holding unit to the planarization member held by a member holding unit, with the planarization member not in contact with the composition on the substrate;
detecting whether the pressing member projected thorough the first projection contacts the substrate; and
determining whether a holding position of the substrate held by the substrate holding unit is correct based on a result of the detecting.

12. The planarization method according to claim 11, further comprising, in a case where the holding position of the substrate is determined to be incorrect, adjusting the holding position of the substrate.

13. The planarization method according to claim 11, further comprising:
in a case where the holding position of the substrate is determined to be correct, projecting, as a second projection, the pressing member in the direction from the substrate to the planarization member with the planarization member not in contact with the composition;
detecting, as a second detection, whether the pressing member projected through the second projection contacts the planarization member; and
determining, as a second determination, whether planarization processing is performable with the planarization member held by the member holding unit based on a result of the second detection.

14. The planarization method according to claim 11, further comprising, after the determining:
bringing the planarization member into contact with the composition;
curing the composition with the planarization member in contact with the composition; and
separating the planarization member from the cured composition,
wherein the pressing member is configured to assist separation by pushing up the planarization member in the direction from the substrate to the planarization member during the separating.

15. The planarization method according to claim 11, wherein, in a case where the holding position of the substrate is determined to be incorrect, planarization processing for bringing the substrate and the planarization member into contact via the composition is not performed.

16. A product manufacturing method, comprising:
planarizing a composition on a substrate using the planarization apparatus according to claim 1;
processing the substrate having the planarized composition; and
manufacturing a product from the processed substrate.
